(19) United States
(12) Patent Application Publication
(10) Pub. No.: US 2026/0351317 A1
(43) Pub. Date: Nov. 5, 2026

(54) GANGED READ OPERATION FOR MULTIPLE SUB-BLOCKS

(71) Applicant: Micron Technology, Inc., Boise, ID (US)

(72) Inventors: Yu-Chung Lien, San Jose, CA (US); Ting Luo, Santa Clara, CA (US); Zhenming Zhou, San Jose, CA (US)

(21) Appl. No.: 19/739,853

(22) Filed: Jul. 13, 2026

Related U.S. Application Data
(63) Continuation of application No. 18/782,517, filed on Jul. 24, 2024.
(60) Provisional application No. 63/540,481, filed on Sep. 26, 2023.

(51) Int. Cl. G11C 16/26; G11C 16/04; G11C 16/08; G11C 16/10; G11C 16/34

(52) U.S. Cl. CPC G11C 16/26; G11C 16/08; G11C 16/10; G11C 16/3459; G11C 16/0483

(57) ABSTRACT

Methods, systems, and devices for a ganged read operation for multiple sub-blocks are described. The method may include writing a respective first logic state to each memory cell of a set of memory portions and biasing a first word line and a second word line to a first voltage. In some examples, the first word line may correspond to a first memory portion and the second word line may correspond to a second memory portion. Further, the method may include applying a first read pulse to the first word line and a second read pulse to the second word line and reading a second logic state from one or more memory cells of the first memory portion and the second memory portion. Further, the method may include validating the write operation based on reading the second logic state from the memory cells of the first memory portion and the second memory portion.

### CROSS REFERENCE

The present Application for Patent is a continuation of U.S. patent application Ser. No. 18/782,517 by Lien et al., entitled “GANGED READ OPERATION FOR MULTIPLE SUB-BLOCKS,” filed Jul. 24, 2024, which claims priority to and the benefit of U.S. Patent Application No. 63/540,481 by Lien et al., entitled “GANGED READ OPERATION FOR MULTIPLE SUB-BLOCKS,” filed Sep. 26, 2023, each of which is assigned to the assignee hereof, and each of which is expressly incorporated by reference in its entirety herein.

### TECHNICAL FIELD

The following relates to one or more systems for memory, including ganged read operation for multiple sub-blocks.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports ganged read operation for multiple sub-blocks in accordance with examples as disclosed herein.

FIG. 2A shows an example of a system that supports ganged read operation for multiple sub-blocks in accordance with examples as disclosed herein.

FIG. 2B shows an example of a voltage timing diagram that supports ganged read operation for multiple sub-blocks in accordance with examples as disclosed herein.

FIG. 3 shows a block diagram of a memory system that supports ganged read operation for multiple sub-blocks in accordance with examples as disclosed herein.

FIGS. 4 through 7 show flowcharts illustrating a method or methods that support ganged read operation for multiple sub-blocks in accordance with examples as disclosed herein.

### DETAILED DESCRIPTION

A memory system may include a memory array (e.g., three-dimensional array). The memory array may include a set of word lines and a set of bit lines. In some examples, the word lines may run perpendicular to the bit lines and, at each intersection of a bit line and a word line, there may be a memory cell configured to a store a logic state (e.g., a “1” or a “0”). The memory array may be partitioned into blocks and each block may include a respective subset of word lines and a respective subset of bit lines. Further, each block may be partitioned into a set of sub-blocks and, in some examples, multiple sub-blocks of a block may include one or more common bit lines and each sub-block of the block may correspond to a same word line or word line plane.

In some examples, the memory system may encounter a data loss event (or uncorrectable errors in data). The data loss event may occur when an access operation (e.g., a read operation, a write operation) fails at the memory system and the memory system is unable to recover the associated data. Factors that may cause the access operation to fail may include defects in the access lines of the memory system (e.g., word lines or bits lines), read disturb, etc. These factors may cause a threshold voltage distribution of the memory cells to shift or widen, which may result in an incorrect logic state being stored or read from the memory cells during a respective access operation.

Upon detecting the data loss event, the memory system may implement redundant array of independent NANDs (RAIN). Using RAIN, the memory system may create a backup of the memory stored in the array (e.g., in SRAM) in the case of the data loss event. However, implementation of RAIN may decrease valuable storage space and may decrease the overall performance of the memory system.

To prevent a data loss event, the memory device may perform one or more error detection procedures. For example, the memory system may perform a program verify operation. During the program verify operation, the memory system may program memory cells of the memory array and verify the programming by applying a voltage (e.g., a ramped voltage) to memory cells being verified. However, the program verify operation may be unable to cover scenarios in which the memory cell is over-programmed or scenarios in which the threshold voltage distribution of the memory cell has shifted. Additionally, or alternatively, the memory system may apply a read scan to all word lines to detect errors, but performing such read scan may be time consuming, resulting in performance drops in the memory system. Additionally, or alternatively, the memory system may employ charge pump count monitor (CPCM) to detect word line leakage. But CPCM may only allow the memory system to detect intrinsic factors negatively impacting the programming of memory cells (e.g., standard deviation of memory cells) and other negative factors (e.g., extrinsic factors such as access line defects) may go unnoticed.

As described herein, the memory system may perform a ganged read on multiple sub-blocks to verify the programming of memory cells. In some examples, the memory system may write a logic state to each memory cell included in a set of sub-blocks. Further, the memory system may bias a first word line and a second word line to a first voltage (e.g., a pre-read voltage). The first word line may correspond to a first sub-block of the set of sub-blocks and the second word line may correspond to a second sub-block of the set of sub-blocks. In some examples, the memory system may bias the first word line and the second word line to the first voltage during a same time duration (e.g., seamless read).

The memory system may bias the first word lines to a second voltage (e.g., a read voltage) and read the logic states of one or more memory cells corresponding to the first word line included in the first sub-block. Additionally, the memory system may bias the second word line to a third voltage (e.g., a read voltage) and read the logic states of one or more memory cells corresponding to the second word line included in the second sub-block. In some examples, the memory system may apply the second voltage to the first word line prior to applying the third voltage to the second word line.

Upon reading the logic states, the memory system may compare each of the respective logic states read from the memory cells to each of the respective logic states stored at the memory cells. For each mismatch, the memory system may increment a counter and, if a value of the counter goes a above a threshold (e.g., satisfies a threshold), the memory system may detect that there are errors in the data and the memory device may perform one or more actions to refresh data stored at the set of sub-blocks. Using such methods may allow the memory system to detect factors that may contribute to a data loss event, which may reduce the chances of a data loss event occurring. Further, the memory system may perform the verification in less time when compared to other methods (e.g., a read scan).

Features of the disclosure are illustrated and described in the context of systems, devices, and circuits. Features of the disclosure are further illustrated and described in the context of a voltage timing diagram and flowcharts.

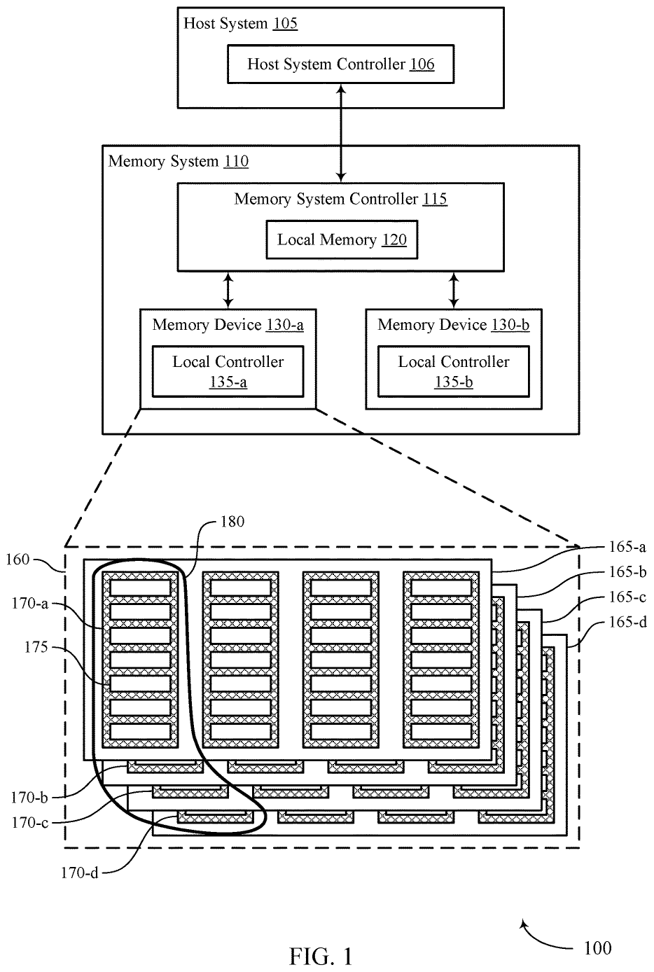

FIG. 1 shows an example of a system 100 that supports ganged read operation for multiple sub-blocks in accordance with examples as disclosed herein. The system 100 includes a host system 105 coupled with a memory system 110. The system 100 may be included in a computing device such as a desktop computer, a laptop computer, a network server, a mobile device, a vehicle (e.g., airplane, drone, train, automobile, or other conveyance), an Internet of Things (IOT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on a same die or within a same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single-level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in a same page 175 may share (e.g., be coupled with) a common word line, and memory cells in a same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, to update some data within a block 170 while retaining other data within the block 170, the memory device 130 may copy the data to be retained to a new block 170 and write the updated data to one or more remaining pages of the new block 170. The memory device 130 (e.g., the local controller 135) or the memory system controller 115 may mark or otherwise designate the data that remains in the old block 170 as invalid or obsolete and may update a logical-to-physical (L2P) mapping table to associate the logical address (e.g., LBA) for the data with the new, valid block 170 rather than the old, invalid block 170. In some cases, such copying and remapping may be performed instead of erasing and rewriting the entire old block 170 due to latency or wearout considerations, for example. In some cases, one or more copies of an L2P mapping table may be stored within the memory cells of the memory device 130 (e.g., within one or more blocks 170 or planes 165) for use (e.g., reference and updating) by the local controller 135 or memory system controller 115.

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

The system 100 may include any quantity of non-transitory computer readable media that support ganged read operation for multiple sub-blocks. For example, the host system 105 (e.g., a host system controller 106), the memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

In some examples, the memory system 110 may perform a verification operation that includes a ganged read of two or more sub-blocks of a block 170. In such example, the memory device 130 may include a three-dimensional array of memory cells and each block 170 of memory cells may be divided into sub-blocks where each sub-block corresponds to a same word line. The memory system 110 may write a respective first logic state to each memory cell of each of the sub-blocks of the block 170. Further, the memory system 110 may bias a first word line and a second word line of the block 170 to a first voltage (e.g., pre-read voltage). In some examples, the first word line may correspond to a first sub-block of the block 170 and the second word line may correspond to a second sub-block of the block 170.

Additionally, the memory system 110 may apply a first read pulse to the first word line and a second read pulse to the second word line and read a second logic state from one or more memory cells of the first sub-block and the second sub-block. The memory system 110 may then validate the write operation based on reading the second logic state and bias the first word line and the second word line to a second voltage (e.g., ground voltage) to conclude the verification operation. Using such methods may allow the memory system 110 to detect factors that may contribute to a data loss event, which may reduce the chances of a data loss event occurring. Further, the memory system 110 may perform the verification in less time when compared to other methods (e.g., a read scan).

In addition to applicability in memory systems 110 as described herein, techniques for performing a ganged read operation on multiple sub-blocks may be generally implemented to improve the performance (including gaming) of various electronic devices and systems. Some electronic device applications, including gaming and other high-performance applications, may be associated with relatively high processing requirements while also benefitting from relatively quick response times to improve user experience. As such, increasing processing speed, decreasing response times, or otherwise improving the performance electronic devices may be desirable. Implementing the techniques described herein may improve the performance of electronic devices by improving memory access speeds, which may decrease processing or latency times, improve response times, or otherwise improve user experience, among other benefits.

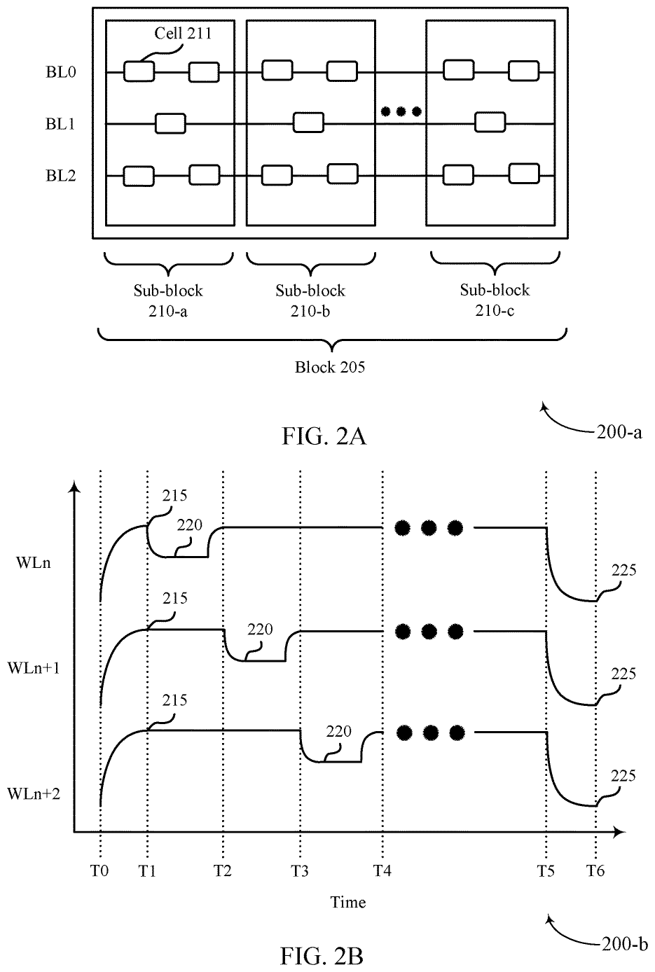

FIG. 2A shows an example of a system 200-a that supports ganged read operation for multiple sub-blocks in accordance with examples as disclosed herein. The system 200-a may include aspects of a system 100. For example, the system 200-a may be an example of a memory device 130 as described with reference to FIG. 1.

FIG. 2B shows an example of a voltage timing diagram 200-b that supports ganged read operation for multiple sub-blocks in accordance with examples as disclosed herein. In some examples, the voltage timing diagram 200-b may be implemented by aspects of the system 100. For example, the voltage timing diagram 200-b may be implemented by a memory system 110, or more specifically, a memory system controller 115 or a local controller 135 as described with reference to FIG. 1.

In some examples, the system 200-a may include a block 205 that is representative of a three-dimensional array of memory cells 211. Further, the block 205 may be divided into a set of sub-blocks 210. For example, as shown in FIG. 2A, the block 205 may include a sub-block 210-a, a sub-block 210-b, and a sub-block 210-c. Each sub-block 210 may include one or more memory cells 211 that is coupled with a same word line or word lines plane. For example, the memory cells 211 of the sub-block 210-a may be coupled with a WL0, the memory cells 211 of the sub-block 210-b may be coupled with a WL1, and the memory cells 211 of the sub-block 210-c may be coupled with a WL2. Further, each memory cell 211 of the sub-blocks 210 may be coupled with a bit line. Unlike the word lines, bit lines may be common between two or more sub-blocks 210. For example, as shown in FIG. 2A, the BL0, the BL1, and the BL2 may be coupled with respective memory cells 211 of the sub-block 210-a, the sub-block 210-b, and the sub-block 210-c. In some examples, the memory cells 211 included in the block 205 may be configured to store a logic state that includes one bit (e.g., a SLC) or multiple bits (e.g., MLCs, TLCs, or QLCs).

In some examples, the memory system may perform a verification operation to validate the programming of the memory cells 211 of the block 205. The voltage timing diagram 200-b may illustrate voltages of word lines of the block 205 over time during the verification procedure. In some examples, prior to the verification procedure, the memory system may program the memory cells 211 of the block 205. To program the memory cells 211, the memory system may apply a one or more programming pulses to the word lines of the block 205 (e.g., the WL0, the WL1, and the WL2).

After programming the memory cells 211, the memory system may initiate the verification procedure. In some examples, the memory system may initiate the verification procedure in response to receiving a command from a host system indicating to perform the verification procedure. Additionally, the command or other signaling from the host system may provide an indication (e.g., to the memory system) of which of the sub-blocks 210 or blocks 205 to perform the verification procedure on (e.g., using a block address). Further, the memory system may receive signaling indicating a quantity of sub-blocks 210 (e.g., more than one) to apply the verification procedure to. In some examples, the memory system may perform the verification procedure directly after programming or after the block 205 is closed. As shown in FIG. 2B, T0 marks the start of the verification operation.

From T0 to T1, the memory system may bias the word lines of the block 205 to a voltage 215 (or a pre-read voltage). For example, from T0 to T1, the memory system may bias a WLₙ, a WLₙ₊₁, and a WLₙ₊₂ to the voltage 215. In some examples, the WLₙ, the WLₙ₊₁, and the WLₙ₊₂ may be an example of the WL0, the WL1, and the WL2, respectively. In some examples, the WLₙ, the WLₙ₊₁, and the WLₙ₊₂ may correspond to consecutive sub-blocks 210 or may correspond to nonconsecutive sub-blocks 210 in which one or more of the sub-blocks 210 are separated by one or more intervening sub-blocks 210. Further, as shown in FIG. 2B, the memory system may bias the word lines to the voltage 215 during a same duration (e.g., from T0 to T1). That is, the memory system may perform word line ramping up on multiple word lines at the same time. This procedure of ramping up the multiple word lines during a same duration may be known as a seamless read operation and may allow the memory system to skip read overhead associated with ramping up multiple word lines during different durations.

From T1 to T4, the memory system may perform a ganged read operation as part of the verification operation. During the ganged read operation, the memory system may read logic states of memory cells 211 corresponding to the two or more sub-blocks 210. In some examples, the memory system may read memory cells 211 corresponding to different sub-blocks during different durations. For example, from T1 to T2, the memory system may bias the WLₙ to the voltage 220 (e.g., by applying a first read pulse). From T2 to T3, the memory system may bias the WLₙ₊₁ to the voltage 220 (e.g., by applying a second read pulse). From T3 to T4, the memory system may bias the WLₙ₊₂ to the voltage 220 (e.g., by applying a third read pulse). While one of the word lines is biased to the voltage 220, the memory system may keep the other word line(s) at a constant voltage (e.g., the voltage 215). Further, after biasing a respective word line to the voltage 220, the memory system may bias the respective word line to the voltage 215 (e.g., at T2 for WLₙ, T3 for WLₙ₊₁, and T4 for WLₙ₊₂).

If the block 205 includes SLCs, the voltage 220 may correspond to a voltage between a threshold voltage distribution associated with a logic state of 0 and a threshold voltage distribution associated with a logic state of 1. Alternatively, if the block 205 includes MLCs, TLCs, and QLCs, the voltage 220 may correspond to a last read level. For example, for TLCs, the voltage 220 may corresponding to a voltage between a threshold voltage distribution associated with a logic state of 001 and a threshold voltage distribution associated with a logic state of 000. However, it is understood that the voltage 220 may correspond to any read level (e.g., any fixed level) associated with MLCs, TLCs, and QLCs and not just the last read level. Further, multiple read pulses may be applied to the two or more word lines (not shown in FIG. 2B).

When the voltage 220 is applied to a respective word line, a signal may be generated on respective bit lines (e.g., BL0 through BL2) and the memory system may determine a logic state of each of the memory cells 211 coupled with the respective word line based on the signal. In some examples, the memory system may read only a single bit of data from each memory cell 211 (e.g., due to applying only a single read pulse) and in some examples, the single bit may be associated with a highest level written to each of the memory cells 211.

If an error in the data occurs prior to or during the read operation, a logic state read from a memory cell 211 may be different from a logic state stored at the memory cell 211 during programming. Thus, upon determining the logic states, the memory system may compare each logic state read from the memory cells 211 to a logic state programmed to a respective memory cell 211. For each mismatch in logic states, the memory system may increment a first counter (e.g., a count fail byte (CFByte)). If the first counter exceeds a first threshold, the memory system may identify that there are errors in the data and the memory system may attempt to recover the data using a refresh operation (e.g., via RAIN). Alternatively, if the first counter does not exceed the first threshold, the memory system may validate the programming operation (or write operation) and identify that there no errors or an acceptable amount of errors (e.g., below a threshold) in the data.

Additionally, or alternatively, the memory system may increment a second counter each time the memory system determines a certain logic state (e.g., a logic state of 1). If the counter does not exceed a threshold, the memory system may identify that there are errors in the data and the memory system may attempt to recover the data using a refresh operation (e.g., via RAIN). In such examples, the memory system may program a percentage of the memory cells 211 to the certain logic state and the second threshold may be based on the percentage. Alternatively, if the second counter does exceed or meet the second threshold, the memory system may validate the programming operation (or write operation) and identify that there no errors or an acceptable amount of errors (e.g., below a threshold) in the data.

The ganged read operation performed on the word lines may conclude at T4 and the memory system may maintain the word lines at a constant voltage (e.g., the voltage 220) until T5. From T5 to T6, the memory system may end the verification operation by biasing the word lines to the voltage 225 (e.g., a voltage less than the voltage 220 or ground). For example, from T5 to T6, the memory system may bias the WLₙ, the WLₙ₊₁, and the WLₙ₊₂ to the voltage 225. As shown in FIG. 2B, the memory system may bias the two or more word lines during a same duration (e.g., from T5 to T6). That is, the memory system ramp down the two or more word lines during the same time.

Using the methods as described herein may allow the memory system to detect when there are errors in the data that may cause a data loss event and thus, the data loss event may be avoided. Further, the methods as described herein may allow the memory system to perform a read of the block 205 in less time when compared to other methods (e.g., traditional read scan).

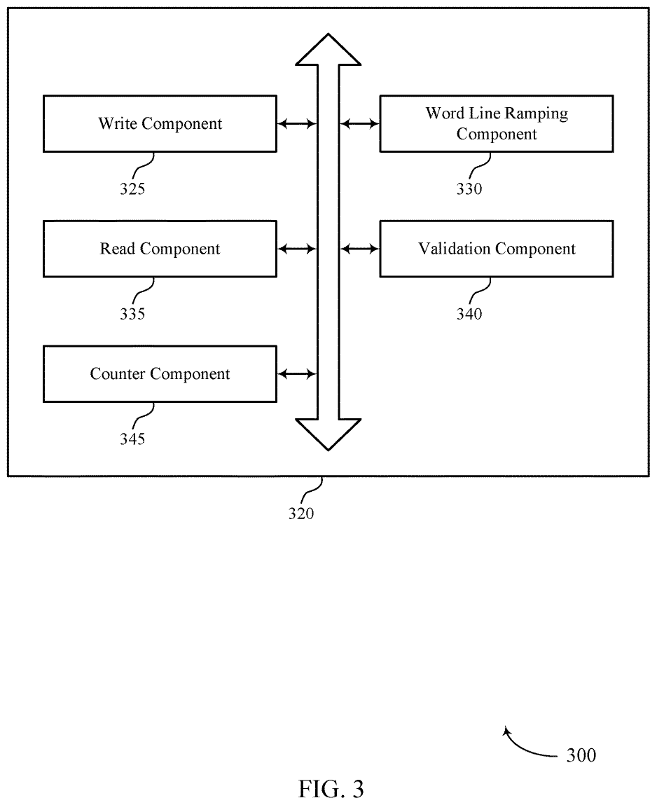

FIG. 3 shows a block diagram 300 of a memory system 320 that supports ganged read operation for multiple sub-blocks in accordance with examples as disclosed herein. The memory system 320 may be an example of aspects of a memory system as described with reference to FIGS. 1 through 2. The memory system 320, or various components thereof, may be an example of means for performing various aspects of ganged read operation for multiple sub-blocks as described herein. For example, the memory system 320 may include a write component 325, a word line ramping component 330, a read component 335, a validation component 340, a counter component 345, or any combination thereof. Each of these components, or components of subcomponents thereof (e.g., one or more processors, one or more memories), may communicate, directly or indirectly, with one another (e.g., via one or more buses).

The write component 325 may be configured as or otherwise support a means for writing a respective first logic state to each memory cell of each of a plurality of memory portions. The word line ramping component 330 may be configured as or otherwise support a means for biasing a first word line and a second word line of a plurality of word lines to a first voltage based at least in part on receiving a command to validate a write operation, where the first word line corresponds to a first memory portion of the plurality of memory portions and the second word line corresponds to a second memory portion of the plurality of memory portions. The read component 335 may be configured as or otherwise support a means for applying a first read pulse to the first word line and a second read pulse to the second word line based at least in part on biasing the first word line and the second word line to the first voltage. In some examples, the read component 335 may be configured as or otherwise support a means for reading a second logic state from one or more memory cells of the first memory portion and the second memory portion based at least in part on applying the first read pulse to the first word line and the second read pulse to the second word line. The validation component 340 may be configured as or otherwise support a means for validating the write operation based at least in part on reading the second logic state from the one or more memory cells of the first memory portion and the second memory portion.

In some examples, to support validating the write operation, the counter component 345 may be configured as or otherwise support a means for incrementing a counter for each memory cell of the one or more memory cells that stores the second logic state that is different than the first logic state written to a respective memory cell of the one or more memory cells, where validating the write operation is based at least in part on a value of the counter being failing to satisfy a threshold value.

In some examples, to support validating the write operation, the counter component 345 may be configured as or otherwise support a means for incrementing a counter for each memory cell of the one or more memory cells that stores the second logic state that is the same as a logic state written to a respective memory cell of the one or more memory cells, where validating the write operation is based at least in part on a value of the counter satisfying a threshold value.

In some examples, to support applying the first read pulse and the second read pulse, the read component 335 may be configured as or otherwise support a means for biasing the first word line and the second word line of the plurality of word lines to a second voltage that corresponds to a threshold voltage distribution of a plurality of threshold voltage distributions associated with the first logic state.

In some examples, the word line ramping component 330 may be configured as or otherwise support a means for biasing the first word line and the second word line of the plurality of word lines to a second voltage based at least in part on reading the second logic state from the one or more memory cells, where the second voltage is less than the first voltage.

In some examples, to support applying the first read pulse and the second read pulse, the read component 335 may be configured as or otherwise support a means for applying the first read pulse and the second read pulse during a respective first duration and second duration, where the first duration occurs prior to the second duration, and where the first duration and the second duration are non-overlapping durations.

In some examples, to support biasing the first word line and the second word line to the first voltage, the word line ramping component 330 may be configured as or otherwise support a means for biasing the first word line and the second word line to the first voltage during a same duration. In some examples, the validation component 340 may be configured as or otherwise support a means for receiving signaling indicating a quantity of memory portions greater than one, where reading the second logic state is based on the quantity of memory sections.

In some examples, the word line ramping component 330 may be configured as or otherwise support a means for biasing a third word line of the plurality of word lines to the first voltage based at least in part on receiving the command to validate the write operation, where the third word line corresponds to a third memory portion of the plurality of memory portions. In some examples, the read component 335 may be configured as or otherwise support a means for applying a third read pulse to the third word line based at least in part on biasing the third word line to the first voltage, where reading the second logic state from the one or more memory cells the first memory portion and the second memory portion is based at least in part on applying the third read pulse to the third word line.

In some examples, the first memory portion and the second memory portion include consecutive memory portions or the first memory portion and the second memory portion are separated from one another by one or more intervening memory portion. In some examples, the memory cells include SLCs, MLCs, or TLCs.

In some examples, the read component 335 may be configured as or otherwise support a means for reading, during a first duration, a first logic state from at least a first memory cell coupled with a first word line of a plurality of word lines. In some examples, the read component 335 may be configured as or otherwise support a means for reading, during a second duration, a second logic state from at least a second memory cell coupled with a second word line of the plurality of word lines based at least in part on reading the first logic state from at least the first memory cell. In some examples, the validation component 340 may be configured as or otherwise support a means for verifying, during a third duration and based at least in part on reading the second logic state from the second memory cell, that the first logic state and the second logic state written to at least the first memory cell and the second memory cell were written during respective write operations preceding the first duration.

In some examples, to support reading the first logic state and the second logic state from the first memory cell and the second memory cell, the read component 335 may be configured as or otherwise support a means for reading a single bit of data from each of the first memory cell and the second memory cell.

In some examples, to support verifying that the first logic state and the second logic state written to the first memory cell and the second memory cell were written during respective write operations preceding the first duration, the validation component 340 may be configured as or otherwise support a means for comparing the respective bits read from each of the first memory cell and the second memory cell to a respective bit written to each of the first memory cell and the second memory cell during the respective write operations.

In some examples, the single bit read from each of the first memory cell and the second memory cell is associated with a highest level written to each of the multi-level memory cells.

In some examples, the validation component 340 may be configured as or otherwise support a means for receiving a command based at least in part on reading the second logic state from the second memory cell, where verifying that the first logic state and the second logic state were written to the first memory cell and the second memory cell were written during respective write operations preceding the first duration is based at least in part on receiving the command. In some examples, the first duration, the second duration, and the third duration are consecutive durations.

In some examples, the read component 335 may be configured as or otherwise support a means for reading, during a first duration, a first logic state from at least a first memory cell coupled with a first word line of a plurality of word lines. In some examples, the read component 335 may be configured as or otherwise support a means for reading, during a second duration, a second logic state from at least a second memory cell coupled with a second word line of the plurality of word lines based at least in part on reading the first logic state from at least the first memory cell. In some examples, the validation component 340 may be configured as or otherwise support a means for verifying, during a third duration and based at least in part on reading the second logic state from the second memory cell, that the first logic state and the second logic state written to at least the first memory cell and the second memory cell were written during respective write operations preceding the first duration.

In some examples, the described functionality of the memory system 320, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 320, or various components thereof, may be implemented at least in part by instructions (e.g., stored in memory, non-transitory computer-readable medium) executable by such at least one processor.

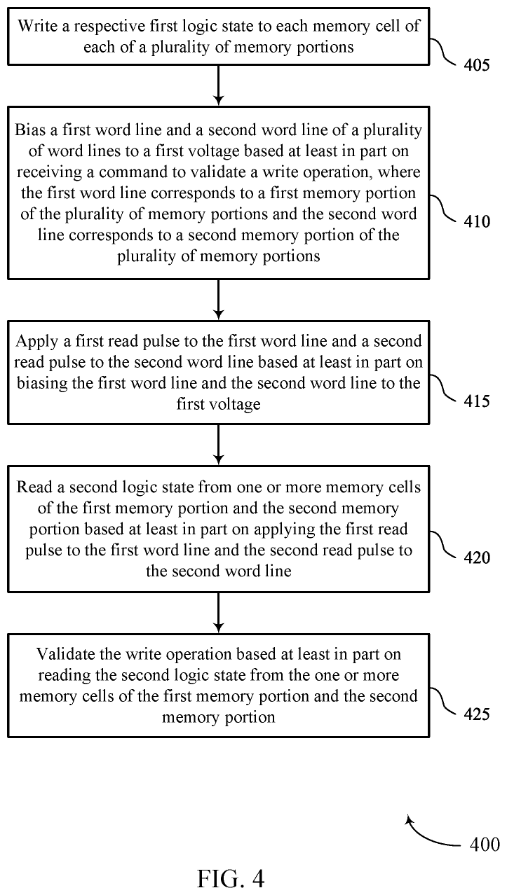

FIG. 4 shows a flowchart illustrating a method 400 that supports ganged read operation for multiple sub-blocks in accordance with examples as disclosed herein. The operations of method 400 may be implemented by a memory system or its components as described herein. For example, the operations of method 400 may be performed by a memory system as described with reference to FIGS. 1 through 3. In some examples, a memory system may execute a set of instructions to control the functional elements of the device to perform the described functions. Additionally, or alternatively, the memory system may perform aspects of the described functions using special-purpose hardware.

At 405, the method may include writing a respective first logic state to each memory cell of each of a plurality of memory portions. In some examples, aspects of the operations of 405 may be performed by a write component 325 as described with reference to FIG. 3.

At 410, the method may include biasing a first word line and a second word line of a plurality of word lines to a first voltage based at least in part on receiving a command to validate a write operation, where the first word line corresponds to a first memory portion of the plurality of memory portions and the second word line corresponds to a second memory portion of the plurality of memory portions. In some examples, aspects of the operations of 410 may be performed by a word line ramping component 330 as described with reference to FIG. 3.

At 415, the method may include applying a first read pulse to the first word line and a second read pulse to the second word line based at least in part on biasing the first word line and the second word line to the first voltage. In some examples, aspects of the operations of 415 may be performed by a read component 335 as described with reference to FIG. 3.

At 420, the method may include reading a second logic state from one or more memory cells of the first memory portion and the second memory portion based at least in part on applying the first read pulse to the first word line and the second read pulse to the second word line. In some examples, aspects of the operations of 420 may be performed by a read component 335 as described with reference to FIG. 3.

At 425, the method may include validating the write operation based at least in part on reading the second logic state from the one or more memory cells of the first memory portion and the second memory portion. In some examples, aspects of the operations of 425 may be performed by a validation component 340 as described with reference to FIG. 3.

In some examples, an apparatus as described herein may perform a method or methods, such as the method 400. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for writing a respective first logic state to each memory cell of each of a plurality of memory portions; biasing a first word line and a second word line of a plurality of word lines to a first voltage based at least in part on receiving a command to validate a write operation, where the first word line corresponds to a first memory portion of the plurality of memory portions and the second word line corresponds to a second memory portions of the plurality of memory portions; applying a first read pulse to the first word line and a second read pulse to the second word line based at least in part on biasing the first word line and the second word line to the first voltage; reading a second logic state from one or more memory cells of the first memory portion and the second memory portion based at least in part on applying the first read pulse to the first word line and the second read pulse to the second word line; and validating the write operation based at least in part on reading the second logic state from the one or more memory cells of the first memory portion and the second memory portion.

Aspect 2: The method, apparatus, or non-transitory computer-readable medium of aspect 1, where validating the write operation includes operations, features, circuitry, logic, means, or instructions, or any combination thereof for incrementing a counter for each memory cell of the one or more memory cells that stores the second logic state that is different than the first logic state written to a respective memory cell of the one or more memory cells, where validating the write operation is based at least in part on a value of the counter being failing to satisfy a threshold value.

Aspect 3: The method, apparatus, or non-transitory computer-readable medium of any of aspects 1 through 2, where validating the write operation includes operations, features, circuitry, logic, means, or instructions, or any combination thereof for incrementing a counter for each memory cell of the one or more memory cells that stores the second logic state that is the same as a logic state written to a respective memory cell of the one or more memory cells, where validating the write operation is based at least in part on a value of the counter satisfying a threshold value.

Aspect 4: The method, apparatus, or non-transitory computer-readable medium of any of aspects 1 through 3, where applying the first read pulse and the second read pulse includes operations, features, circuitry, logic, means, or instructions, or any combination thereof for biasing the first word line and the second word line of the plurality of word lines to a second voltage that corresponds to a threshold voltage distribution of a plurality of threshold voltage distributions associated with the first logic state.

Aspect 5: The method, apparatus, or non-transitory computer-readable medium of any of aspects 1 through 4, further including operations, features, circuitry, logic, means, or instructions, or any combination thereof for biasing the first word line and the second word line of the plurality of word lines to a second voltage based at least in part on reading the second logic state from the one or more memory cells, where the second voltage is less than the first voltage.

Aspect 6: The method, apparatus, or non-transitory computer-readable medium of any of aspects 1 through 5, where applying the first read pulse and the second read pulse includes operations, features, circuitry, logic, means, or instructions, or any combination thereof for applying the first read pulse and the second read pulse during a respective first duration and second duration, where the first duration occurs prior to the second duration, and where the first duration and the second duration are non-overlapping durations.

Aspect 7: The method, apparatus, or non-transitory computer-readable medium of any of aspects 1 through 6, where biasing the first word line and the second word line to the first voltage includes operations, features, circuitry, logic, means, or instructions, or any combination thereof for biasing the first word line and the second word line to the first voltage during a same duration.

Aspect 8: The method, apparatus, or non-transitory computer-readable medium of any of aspects 1 through 7, further including operations, features, circuitry, logic, means, or instructions, or any combination thereof for receiving signaling indicating a quantity of memory portions greater than one, where reading the second logic state is based on the quantity of memory sections.

Aspect 9: The method, apparatus, or non-transitory computer-readable medium of any of aspects 1 through 8, further including operations, features, circuitry, logic, means, or instructions, or any combination thereof for biasing a third word line of the plurality of word lines to the first voltage based at least in part on receiving the command to validate the write operation, where the third word line corresponds to a third memory portion of the plurality of memory portions and applying a third read pulse to the third word line based at least in part on biasing the third word line to the first voltage, where reading the second logic state from the one or more memory cells the first memory portion and the second memory portion is based at least in part on applying the third read pulse to the third word line.

Aspect 10: The method, apparatus, or non-transitory computer-readable medium of any of aspects 1 through 9, where the first memory portion and the second memory portion include consecutive memory portions or the first memory portion and the second memory portion are separated from one another by one or more intervening memory portions.

Aspect 11: The method, apparatus, or non-transitory computer-readable medium of any of aspects 1 through 10, where the memory cells include SLCs, MLCs, or TLCs.

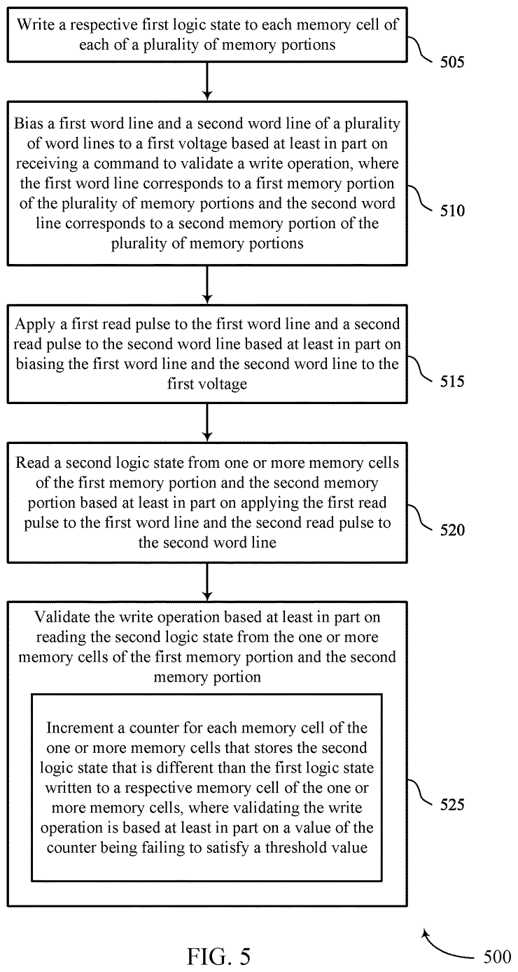

FIG. 5 shows a flowchart illustrating a method 500 that supports ganged read operation for multiple sub-blocks in accordance with examples as disclosed herein. The operations of method 500 may be implemented by a memory system or its components as described herein. For example, the operations of method 500 may be performed by a memory system as described with reference to FIGS. 1 through 3. In some examples, a memory system may execute a set of instructions to control the functional elements of the device to perform the described functions. Additionally, or alternatively, the memory system may perform aspects of the described functions using special-purpose hardware.

At 505, the method may include writing a respective first logic state to each memory cell of each of a plurality of memory portions. In some examples, aspects of the operations of 505 may be performed by a write component 325 as described with reference to FIG. 3.

At 510, the method may include biasing a first word line and a second word line of a plurality of word lines to a first voltage based at least in part on receiving a command to validate a write operation, where the first word line corresponds to a first memory portion of the plurality of memory portions and the second word line corresponds to a second memory portion of the plurality of memory portions. In some examples, aspects of the operations of 510 may be performed by a word line ramping component 330 as described with reference to FIG. 3.

At 515, the method may include applying a first read pulse to the first word line and a second read pulse to the second word line based at least in part on biasing the first word line and the second word line to the first voltage. In some examples, aspects of the operations of 515 may be performed by a read component 335 as described with reference to FIG. 3.

At 520, the method may include reading a second logic state from one or more memory cells of the first memory portion and the second memory portion based at least in part on applying the first read pulse to the first word line and the second read pulse to the second word line. In some examples, aspects of the operations of 520 may be performed by a read component 335 as described with reference to FIG. 3.

At 525, the method may include validating the write operation based at least in part on reading the second logic state from the one or more memory cells of the first memory portion and the second memory portion. In some examples, the method of validating the write operation may include incrementing a counter for each memory cell of the one or more memory cells that stores the second logic state that is different than the first logic state written to a respective memory cell of the one or more memory cells, where validating the write operation is based at least in part on a value of the counter being failing to satisfy a threshold value. In some examples, aspects of the operations of 525 may be performed by a validation component 340 as described with reference to FIG. 3.

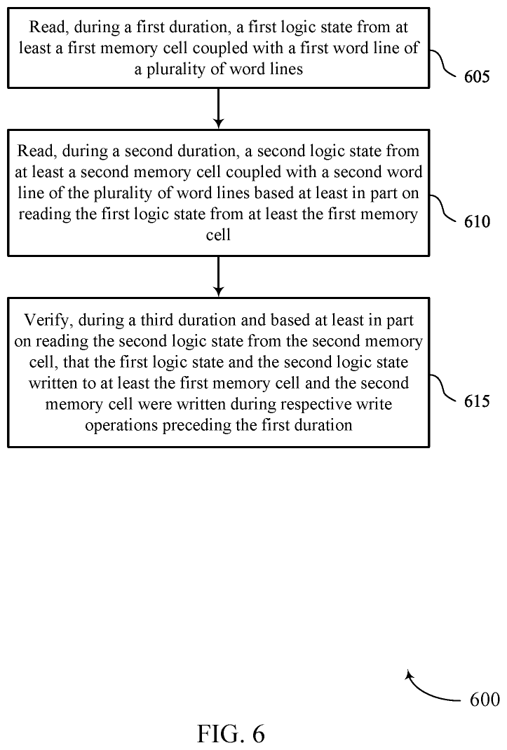

FIG. 6 shows a flowchart illustrating a method 600 that supports ganged read operation for multiple sub-blocks in accordance with examples as disclosed herein. The operations of method 600 may be implemented by a memory system or its components as described herein. For example, the operations of method 600 may be performed by a memory system as described with reference to FIGS. 1 through 3. In some examples, a memory system may execute a set of instructions to control the functional elements of the device to perform the described functions. Additionally, or alternatively, the memory system may perform aspects of the described functions using special-purpose hardware.

At 605, the method may include reading, during a first duration, a first logic state from at least a first memory cell coupled with a first word line of a plurality of word lines. In some examples, aspects of the operations of 605 may be performed by a read component 335 as described with reference to FIG. 3.

At 610, the method may include reading, during a second duration, a second logic state from at least a second memory cell coupled with a second word line of the plurality of word lines based at least in part on reading the first logic state from at least the first memory cell. In some examples, aspects of the operations of 610 may be performed by a read component 335 as described with reference to FIG. 3.

At 615, the method may include verifying, during a third duration and based at least in part on reading the second logic state from the second memory cell, that the first logic state and the second logic state written to at least the first memory cell and the second memory cell were written during respective write operations preceding the first duration. In some examples, aspects of the operations of 615 may be performed by a validation component 340 as described with reference to FIG. 3.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 12: A method, apparatus, or non-transitory computer-readable medium including operations, features, circuitry, logic, means, or instructions, or any combination thereof for reading, during a first duration, a first logic state from at least a first memory cell coupled with a first word line of a plurality of word lines; reading, during a second duration, a second logic state from at least a second memory cell coupled with a second word line of the plurality of word lines based at least in part on reading the first logic state from at least the first memory cell; and verifying, during a third duration and based at least in part on reading the second logic state from the second memory cell, that the first logic state and the second logic state written to at least the first memory cell and the second memory cell were written during respective write operations preceding the first duration.

Aspect 13: The method, apparatus, or non-transitory computer-readable medium of aspect 12, where reading the first logic state and the second logic state from the first memory cell and the second memory cell includes operations, features, circuitry, logic, means, or instructions, or any combination thereof for reading a single bit of data from each of the first memory cell and the second memory cell.

Aspect 14: The method, apparatus, or non-transitory computer-readable medium of aspect 13, where verifying that the first logic state and the second logic state written to the first memory cell and the second memory cell were written during respective write operations preceding the first duration includes operations, features, circuitry, logic, means, or instructions, or any combination thereof for comparing the respective bits read from each of the first memory cell and the second memory cell to a respective bit written to each of the first memory cell and the second memory cell during the respective write operations.

Aspect 15: The method, apparatus, or non-transitory computer-readable medium of any of aspects 13 through 14, where the single bit read from each of the first memory cell and the second memory cell is associated with a highest level written to each of the multi-level memory cells.

Aspect 16: The method, apparatus, or non-transitory computer-readable medium of any of aspects 12 through 15, further including operations, features, circuitry, logic, means, or instructions, or any combination thereof for receiving a command based at least in part on reading the second logic state from the second memory cell, where verifying that the first logic state and the second logic state were written to the first memory cell and the second memory cell were written during respective write operations preceding the first duration is based at least in part on receiving the command.

Aspect 17: The method, apparatus, or non-transitory computer-readable medium of any of aspects 12 through 16, where the first duration, the second duration, and the third duration are consecutive durations.

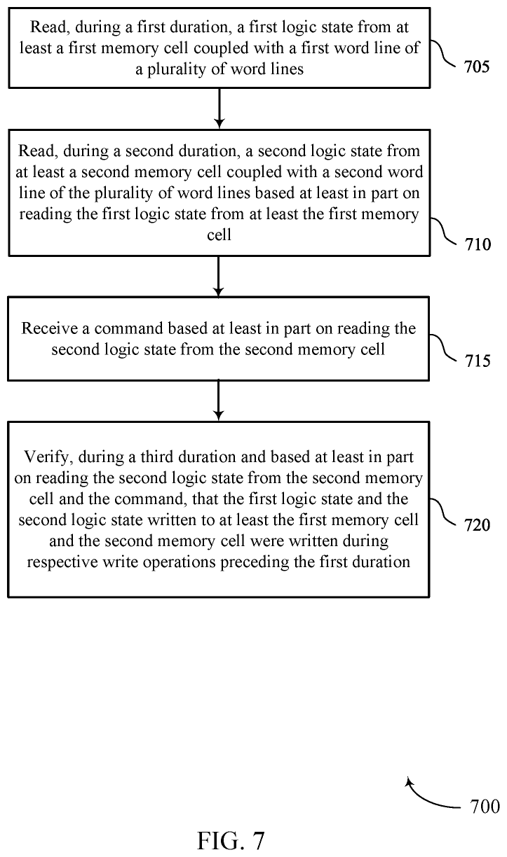

FIG. 7 shows a flowchart illustrating a method 700 that supports ganged read operation for multiple sub-blocks in accordance with examples as disclosed herein. The operations of method 700 may be implemented by a memory system or its components as described herein. For example, the operations of method 700 may be performed by a memory system as described with reference to FIGS. 1 through 3. In some examples, a memory system may execute a set of instructions to control the functional elements of the device to perform the described functions. Additionally, or alternatively, the memory system may perform aspects of the described functions using special-purpose hardware.

At 705, the method may include reading, during a first duration, a first logic state from at least a first memory cell coupled with a first word line of a plurality of word lines. In some examples, aspects of the operations of 705 may be performed by a read component 335 as described with reference to FIG. 3.

At 710, the method may include reading, during a second duration, a second logic state from at least a second memory cell coupled with a second word line of the plurality of word lines based at least in part on reading the first logic state from at least the first memory cell. In some examples, aspects of the operations of 710 may be performed by a read component 335 as described with reference to FIG. 3.

At 715, the method may include receiving a command based at least in part on reading the second logic state from the second memory cell. In some examples, aspects of the operations of 715 may be performed by a validation component 340 as described with reference to FIG. 3.

At 720, the method may include verifying, during a third duration and based at least in part on reading the second logic state from the second memory cell and the command, that the first logic state and the second logic state written to at least the first memory cell and the second memory cell were written during respective write operations preceding the first duration. In some examples, aspects of the operations of 720 may be performed by a validation component 340 as described with reference to FIG. 3.

It should be noted that the described techniques include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 18: A memory system, including: a memory array, including: a plurality of memory portions; a plurality of word lines; and a plurality of bit lines; and a memory controller coupled with the memory array and configured to cause the memory system to: write a respective first logic state to each memory cell of each of the plurality of memory portions; bias a first word line and a second word line of the plurality of word lines to a first voltage based at least in part on receiving a command to validate a write operation, where the first word line corresponds to a first memory portion of the plurality of memory portions and the second word line corresponds to a second memory portion of the plurality of memory portions; apply a first read pulse to the first word line and a second read pulse to the second word line based at least in part on biasing the first word line and the second word line to the first voltage; read a second logic state from one or more memory cells of the first memory portion and the second memory portion based at least in part on applying the first read pulse to the first word line and the second read pulse to the second word line; and validate the write operation based at least in part on reading the second logic state from the one or more memory cells of the first memory portion and the second memory portion.

Aspect 19: The memory system of aspect 18, where, to validate the write operation, the memory controller is configured to cause the memory system to: increment a counter for each memory cell of the one or more memory cells that stores the second logic state that is the same as a logic state written to a respective memory cell of the one or more memory cells, where validating the write operation is based at least in part on a value of the counter satisfying a threshold value.

Aspect 20: The memory system of any of aspects 18 through 19, where, to validate the write operation, the memory controller is configured to cause the memory system to: increment a counter for each memory cell of the one or more memory cells that stores the second logic state that is different than the first logic state written to a respective memory cell of the one or more memory cells, where validating the write operation is based at least in part on a value of the counter being failing to satisfy a threshold value.

Aspect 21: The memory system of any of aspects 18 through 20, where the first logic state includes more than one bit and where, to apply the first read pulse and the second read pulse, the memory controller is configured to cause the memory system to: bias the first word line and the second word line of the plurality of word lines to a second voltage that corresponds to a threshold voltage distribution of a plurality of threshold voltage distributions associated with the first logic state.

Aspect 22: The memory system of any of aspects 18 through 21, where the memory controller is configured to cause the memory system to: bias the first word line and the second word line of the plurality of word lines to a second voltage based at least in part on reading the second logic state from the one or more memory cells, where the second voltage is less than the first voltage.

Aspect 23: The memory system of any of aspects 18 through 22, where, to apply the first read pulse and the second read pulse, the memory controller is configured to cause the memory system to: apply the first read pulse and the second read pulse during a respective first duration and second duration, where the first duration occurs prior to the second duration, and where the first duration and the second duration are non-overlapping durations.

Aspect 24: The memory system of any of aspects 18 through 23, where, to bias the first word line and the second word line to the first voltage, the memory controller is configured to cause the memory system to: bias the first word line and the second word line to the first voltage during a same duration.

Aspect 25: The memory system of any of aspects 18 through 24, where the memory controller is configured to cause the memory system to: receive signaling indicating a quantity of memory portions greater than one, where reading the second logic state is based on the quantity of memory sections.

Aspect 26: The memory system of any of aspects 18 through 25, where the memory controller is configured to cause the memory system to: bias a third word line of the plurality of word lines to the first voltage based at least in part on receiving the command to validate the write operation, where the third word line corresponds to a third memory portion of the plurality of memory portions; and apply a third read pulse to the third word line based at least in part on biasing the third word line to the first voltage, where reading the second logic state from the one or more memory cells the first memory portion and the second memory portion is based at least in part on applying the third read pulse to the third word line.

Aspect 27: The memory system of any of aspects 18 through 26, where: the first memory portion and the second memory portion line include consecutive memory portions; or the first memory portion and the second memory portion are separated from one another by one or more intervening memory portions.

Aspect 28: The memory system of any of aspects 18 through 27, where the memory cells include SLCs, MLCs, and TLCs.

An apparatus is described. The following provides an overview of aspects of the apparatus as described herein:

Aspect 29: An apparatus, including: a first memory cell coupled with a first word line of a plurality of word lines; a second memory cell coupled with a second word line of a plurality of word lines; and a controller coupled with the first word line and the second word line, where the controller is operable to cause the apparatus to: read, during a first duration, a first logic state from the first memory cell; read, during a second duration, a second logic state from the second memory cell based at least in part on reading the first logic state from the first memory cell; and verify, during a third duration and based at least in part on reading the second logic state from the second memory cell, that the first logic state and the second logic state written to at least the first memory cell and the second memory cell were written during respective write operations preceding the first duration

Aspect 30: The apparatus of aspect 29, where the first memory cell and the second memory cell include multi-level memory cells, where to read the first logic state and the second logic state from the first memory cell and the second memory cell, the controller is operable to cause the apparatus to: read a single bit of data from each of the first memory cell and the second memory cell.

Aspect 31: The apparatus of aspect 30, where to verify that the first logic state and the second logic state written to at least the first memory cell and the second memory cell were written during respective write operations preceding the first duration, the controller is operable to cause the apparatus to: compare the respective bits read from each of the first memory cell and the second memory cell to a respective bit written to each of the first memory cell and the second memory cell during the respective write operations.

Aspect 32: The apparatus of any of aspects 30 through 31, where the single bit read from each of the first memory cell and the second memory cell is associated with a highest level written to each of the multi-level memory cells.

Aspect 33: The apparatus of any of aspects 29 through 32, the controller is operable to cause the apparatus to: receive a command based at least in part on reading the second logic state from the second memory cell, where verifying that the first logic state and the second logic state written to at least the first memory cell and the second memory cell were written during respective write operations preceding the first duration is based at least in part on receiving the command.

Aspect 34: The apparatus of any of aspects 29 through 33, where the first duration, the second duration, and the third duration are consecutive durations.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processor. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of these are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A host system, comprising:
processing circuitry configured to cause the host system to:
transmit, to a memory system coupled with the host system, a command to validate a write operation associated with a plurality of memory portions of the memory system, wherein the plurality of memory portions comprises a first memory portion corresponding to a first word line and a second memory portion corresponding to a second word line; and
transmit, to the memory system, an indication of a quantity of memory portions to apply a verification procedure to, wherein the verification procedure comprises a ganged read of the first memory portion and the second memory portion based at least in part on the quantity of memory portions.

2. The host system of claim 1, wherein the quantity of memory portions is greater than one.

3. The host system of claim 1, wherein the processing circuitry is further configured to cause the host system to:
transmit, to the memory system, signaling indicating which of a plurality of blocks or sub-blocks of the memory system to perform the verification procedure on.

4. The host system of claim 1, wherein the processing circuitry is further configured to cause the host system to:
transmit, to the memory system and prior to transmitting the command to validate the write operation, data for writing to the first memory portion and the second memory portion.

5. The host system of claim 1, further comprising:
a host interface coupled between the host system and the memory system and configured to communicate the command to validate the write operation and the indication of the quantity of memory portions.

6. The host system of claim 5, wherein the host interface comprises one or more of a serial advanced technology attachment (SATA) interface, a Universal Flash Storage (UFS) interface, an embedded Multi-Media Controller (eMMC) interface, a peripheral component interconnect express (PCIe) interface, or a universal serial bus (USB) interface.

7. A method by a host system, comprising:
transmitting, to a memory system coupled with the host system, a command to validate a write operation associated with a plurality of memory portions of the memory system, wherein the plurality of memory portions comprises a first memory portion corresponding to a first word line and a second memory portion corresponding to a second word line; and
transmitting, to the memory system, an indication of a quantity of memory portions to apply a verification procedure to, wherein the verification procedure comprises a ganged read of the first memory portion and the second memory portion based at least in part on the quantity of memory portions.

8. The method of claim 7, wherein the quantity of memory portions is greater than one.

9. The method of claim 7, further comprising:
transmitting, to the memory system, signaling indicating which of a plurality of blocks or sub-blocks of the memory system to perform the verification procedure on.

10. The method of claim 7, further comprising:
transmit, to the memory system and prior to transmitting the command to validate the write operation, data for writing to the first memory portion and the second memory portion.

11. The method of claim 7, wherein transmitting the command to validate the write operation and the indication of the quantity of memory portions is via a host interface coupled between the host system and the memory system.

12. The method of claim 11, wherein the host interface comprises one or more of a serial advanced technology attachment (SATA) interface, a Universal Flash Storage (UFS) interface, an embedded Multi-Media Controller (eMMC) interface, a peripheral component interconnect express (PCIe) interface, or a universal serial bus (USB) interface.

13. A system, comprising:
a memory system comprising a plurality of memory portions; and
a host system coupled with the memory system and comprising first processing circuitry configured to cause the host system to:
transmit, to the memory system, a command to validate a write operation associated with the plurality of memory portions of the memory system, wherein the plurality of memory portions comprises a first memory portion corresponding to a first word line and a second memory portion corresponding to a second word line; and
transmit, to the memory system, an indication of a quantity of memory portions to apply a verification procedure to, wherein the verification procedure comprises a ganged read of the first memory portion and the second memory portion based at least in part on the quantity of memory portions.

14. The system of claim 13, wherein the quantity of memory portions is greater than one.

15. The system of claim 13, wherein the first processing circuitry is further configured to cause the host system to:
transmit, to the memory system, signaling indicating which of a plurality of blocks or sub-blocks of the memory system to perform the verification procedure on.

16. The system of claim 13, wherein the first processing circuitry is further configured to cause the host system to:
transmit, to the memory system and prior to transmitting the command to validate the write operation, data for writing to the first memory portion and the second memory portion.

17. The system of claim 13, further comprising:
a host interface coupled between the host system and the memory system and configured to communicate the command to validate the write operation and the indication of the quantity of memory portions.

18. The system of claim 17, wherein the host interface comprises one or more of a serial advanced technology attachment (SATA) interface, a Universal Flash Storage (UFS) interface, an embedded Multi-Media Controller (eMMC) interface, a peripheral component interconnect express (PCIe) interface, or a universal serial bus (USB) interface.

19. The system of claim 13, wherein the memory system comprises second processing circuitry configured to cause the memory system to:
bias, in response to receiving the command to validate the write operation, the first word line and the second word line to a first voltage; and
apply a first read pulse to the first word line and a second read pulse to the second word line based at least in part on biasing the first word line and the second word line to the first voltage.

20. The system of claim 19, wherein the memory system comprises second processing circuitry configured to cause the memory system to:
read, based at least in part on applying the first read pulse and the second read pulse, a logic state from one or more memory cells of the first memory portion and the second memory portion; and
validate the write operation based at least in part on reading the logic state from the one or more memory cells of the first memory portion and the second memory portion.
